(19) United States
(12) Patent Application Publication
(10) Pub. No.: US 2023/0363209 A1
(43) Pub. Date: Nov. 9, 2023

(54) Display Substrate, Manufacturing Method Thereof, and Display Device

(71) Applicant: BOE Technology Group Co., Ltd., Beijing (CN)

(72) Inventors: Cheng HAN, Beijing (CN); Xin LI, Beijing (CN); Qixiao WU, Beijing (CN); Songquan WU, Beijing (CN); Meng SUN, Beijing (CN); Xing FAN, Beijing (CN); Yansong LI, Beijing (CN)

(21) Appl. No.: 17/633,589

(22) PCT Filed: Mar. 19, 2021
(86) PCT No.: PCT/CN2021/081888

§ 371 Date: Feb. 8, 2022

(51) Int. Cl. H10K 59/122; H10K 59/12

(52) U.S. Cl. CPC H10K 59/122; H10K 59/1201

(57) ABSTRACT

The present disclosure provides a display substrate, a manufacturing method thereof, and a display device. The display substrate includes a pixel define layer and a post spacer disposed on a driving structure layer, wherein the post spacer is disposed on a surface of the pixel define layer at one side away from the driving structure layer, and an orthographic projection of the post spacer on a substrate is within an orthographic projection of the pixel define layer on the substrate; there is a protrusion on a surface of the post spacer at one side away from the driving structure layer, a height of the protrusion being less than 0.2 µm.

### CROSS REFERENCE TO RELATED APPLICATION

The present application is a U.S. National Phase Entry of International Application No. PCT/CN2021/081888 having an international filing date of Mar. 19, 2021. The above-identified application is hereby incorporated by reference.

### TECHNICAL FIELD

The present disclosure relates to, but is not limited to, the field of display technology, and more particularly, to a display substrate, a manufacturing method thereof, and a display device.

### BACKGROUND

As a new type of flat panel display devices, Organic Light Emitting Diode (OLED) display devices have attracted more and more attention. The OLED is an active light emitting component, has the advantages of high luminance, high color saturation, ultra-thinness, wide angle of view, low power consumption, extremely high response speed, and flexibility, etc., so as to better meet the personalized needs of users. With the continuous development of display technology, display devices in which OLEDs are used as light emitting devices and thin film transistors (TFTs) are used for controlling signals have become mainstream products in the field of display at present.

### SUMMARY

The following is a summary about the subject matter described herein in detail. The summary is not intended to limit the protection scope of the claims.

A display substrate includes a pixel define layer and a post spacer disposed on a driving structure layer, wherein the post spacer is disposed on a surface of the pixel define layer at a side away from the driving structure layer, and an orthographic projection of the post spacer on a substrate is within an orthographic projection of the pixel define layer on the substrate; there is a protrusion on a surface of the post spacer at a side away from the driving structure layer, a height of the protrusion being less than 0.2 µm.

In an exemplary implementation, materials of the post spacer include polymer elastomers and nanoparticles, and a proportion of the nanoparticles in the post spacer is 0.5 wt% to 5 wt%.

In an exemplary implementation, a diameter of the nanoparticles is 20 nm to 100 nm.

In an exemplary implementation, the nanoparticles include methyl modified inorganic nanoparticles.

In an exemplary implementation, the methyl modified inorganic nanoparticles include at least one of methyl modified inorganic silicon oxide nanoparticles, methyl modified inorganic zinc oxide nanoparticles and methyl modified inorganic zirconium oxide nanoparticles.

In an exemplary implementation, the polymer elastomers include at least one of polyurethane, polysiloxane and liquid crystal block polymer, an appearance of the polymer elastomers is a cross-linked network formed by chemical connection, and a diameter of meshes of the cross-linked network is 0.5 µm to 2.0 µm.

In an exemplary implementation, a height of the post spacer is 1 µm to 1.5 µm.

In an exemplary implementation, the driving structure layer further includes a pixel define layer, the post spacer is disposed at a side of the pixel define layer away from the substrate, and materials of the pixel define layer and the post spacer are the same.

In an exemplary implementation, the post spacer and the pixel define layer form an integrated structure.

A display device includes the display substrate described above.

A method for manufacturing a display substrate, includes:
forming a pixel define layer and a post spacer on a driving structure layer, wherein the post spacer is disposed on a surface of the pixel define layer at one side away from the driving structure layer, and an orthographic projection of the post spacer on a substrate is within an orthographic projection of the pixel define layer on the substrate;
forming an organic light emitting layer by evaporation using a fine metal mask; and
repairing the post spacer, wherein there is a protrusion on a surface of the post spacer at one side away from the driving structure layer, a height of the protrusion being less than 0.2 µm.

In an exemplary implementation, materials of the post spacer include polymer elastomers and nanoparticles, the polymer elastomers include at least one of polyurethane, polysiloxane and liquid crystal block polymer, an appearance of the polymer elastomers is a cross-linked network formed by chemical connection, and a diameter of meshes of the cross-linked network is 0.5 µm to 2.0 µm; repairing the post spacer includes:

irradiating the post spacer with ultraviolet light, wherein expansion and contraction of the cross-linked network of the polymer elastomers occur under the irradiation of the ultraviolet light, so that the protrusion on the surface of the post spacer changes from sharp to smooth, the height of the protrusion being less than 0.2 µm.

In an exemplary implementation, an irradiation intensity of the ultraviolet light is 5 mW/cm² to 20 mW/cm², and irradiation time of the ultraviolet light is 100 seconds to 300 seconds.

In an exemplary implementation, forming the pixel define layer and the post spacer on the driving structure layer includes: forming the pixel define layer on the driving structure layer; and forming the post spacer on the pixel define layer using a post spacer mask; and

irradiating the post spacer with the ultraviolet light includes providing the post spacer mask on the display substrate and irradiating the post spacer using an ultraviolet light device, the ultraviolet light passing through a light transmission area of the post spacer mask to irradiate the post spacer.

In an exemplary implementation, forming the pixel define layer and the post spacer on the driving structure layer includes: forming the pixel define layer and the post spacer on the driving structure layer through the same running of patterning process using a gray tone mask; and

irradiating the post spacer with the ultraviolet light includes providing the gray tone mask on the display substrate and irradiating the post spacer using an ultraviolet light device, the ultraviolet light passing through a light transmission area of the gray tone mask to irradiate the post spacer.

After the drawings and the detailed description are read and understood, the other aspects may become clear.

### BRIEF DESCRIPTION OF DRAWINGS

The drawings are intended to provide a further understanding of technical schemes of the present disclosure and form a part of the specification, and are used to explain the technical schemes of the present disclosure together with embodiments of the present disclosure, and not intended to form limitations to the technical schemes of the present disclosure. The shapes and sizes of various components in the drawings do not reflect the real proportion, and are only intended to schematically illustrate the contents of the present disclosure.

FIG. 1 is a schematic diagram of a structure of an OLED display device;

FIG. 2 a schematic diagram of a planar structure of a display substrate;

FIG. 3 is a schematic diagram of an equivalent circuit of a pixel driving circuit;

FIG. 4 is a working sequence diagram of a pixel driving circuit;

FIG. 5 is a schematic diagram of a sectional structure of a display substrate in accordance with an exemplary embodiment of the present disclosure;

FIG. 6 is a schematic diagram that a pattern of a driving structure layer is formed in accordance with an exemplary embodiment of the present disclosure;

FIG. 7 is a schematic diagram that a pattern of an anode is formed in accordance with an exemplary embodiment of the present disclosure;

FIG. 8 is a schematic diagram that a pattern of a pixel define layer is formed in accordance with an exemplary embodiment of the present disclosure;

FIG. 9 is a schematic diagram that a pattern of a post spacer is formed in accordance with an exemplary embodiment of the present disclosure;

FIG. 10 is a schematic diagram that a pattern of an organic light emitting layer is formed in accordance with an exemplary embodiment of the present disclosure;

FIG. 11 is a schematic diagram of sharp protrusions occurring on a surface of a post spacer;

FIG. 12 is a schematic diagram of a post spacer after damages to its surface are repaired in accordance with an exemplary embodiment of the present disclosure;

FIG. 13 is a schematic diagram that a pattern of a cathode is formed in accordance with an exemplary embodiment of the present disclosure;

FIG. 14 is a schematic diagram that a pattern of an encapsulation structure layer is formed in accordance with an exemplary embodiment of the present disclosure; and

FIG. 15 is a schematic diagram of a sectional structure of another display substrate in accordance with an exemplary embodiment of the present disclosure.

Description of reference numbers

| | | |
|---|---|---|
| 1-glass carrier plate; | 10-substrate; | 21-anode; |
| 22-pixel define layer; | 23-organic light emitting layer; | 24-cathode; |
| 25-post spacer; | 26- protrusion; | 31-first encapsulation layer; |
| 32-second encapsulation layer; | 33-third encapsulation layer; | 101-transistor; |
| 102-storage capacitor; | 103-driving structure layer | 104-light emitting structure layer; |
| 105-encapsulation structure layer | | |

### DETAILED DESCRIPTION

The embodiments herein may be implemented in many different forms. A person of ordinary skills in the art will readily understand such a fact that implementations and contents may be transformed into various forms without departing from the purpose and scope of the present disclosure. Therefore, the present disclosure should not be interpreted as being limited to the contents recorded in the following implementations only. The embodiments in the present disclosure and features in the embodiments can be arbitrarily combined with each other if there are no conflicts.

Sometimes for clarity, sizes of various constituent elements, thicknesses of layers or areas in the drawings may be exaggerated. Therefore, any one of the implementations of the present disclosure is not necessarily limited to the sizes shown in the drawings, and the shapes and sizes of various components in the drawings do not reflect the real proportion. In addition, the drawings schematically illustrate ideal examples, and any one of the implementations of the present disclosure is not limited to the shapes or numerical values shown in the drawings.

Ordinal numerals such as “first”, “second”, “third” and the like herein are set to avoid confusion of the constituent elements, but not to set a limit in quantity.

For convenience, the terms such as “middle”, “upper”, “lower”, “front”, “back”, “vertical”, “horizontal”, “top”, “bottom”, “inside”, “outside” and the like indicating orientation or position relationships are used herein to illustrate position relationships between the constituent elements with reference to the drawings, and are intended to facilitate the description of the implementations and simplify the description, but not to indicate or imply that the mentioned device or element must have a specific orientation or be constructed and operated in a specific orientation, therefore, they should not be understood as limitations to the present disclosure. The position relationships between the constituent elements may be appropriately changed according to directions of various constituent elements described. Therefore, words and phrases used herein are not limited and appropriate substitutions may be made according to situations.

Unless otherwise specified and defined explicitly, the terms “installed”, “coupled” and “connected” should be understood herein in a broad sense. For example, the connection may be a fixed connection, a detachable connection or an integrated connection, or may be a mechanical connection or an electrical connection, or may be a direct connection, an indirect connection through intermediate components, or communication inside two components. For those skilled in the art, the specific meanings of the above terms in the present disclosure can be understood according to specific situations.

A transistor herein refers to a component which at least includes three terminals, a gate electrode, a drain electrode and a source electrode. The transistor has a channel region between the drain electrode (drain electrode terminal, drain region, or drain) and the source electrode (source electrode terminal, source region, or source), and a current can flow through the drain electrode, the channel region, and the source electrode. The channel region herein refers to a region which the current flows mainly through.

The first electrode herein may be a drain electrode, and the second electrode may be a source electrode, or the first electrode may be a source electrode, and the second electrode may be a drain electrode. In the case that transistors with opposite polarities are used or that a current direction is changed during circuit operation, functions of “the source electrode” and “the drain electrode” may sometimes be exchanged. Therefore, “the source electrode” and “the drain electrode” may be exchanged herein.

“Electrical connection” herein includes a case in which the constituent elements are connected together through an element with a certain electric action. “The element with the certain electric action” is not particularly limited as long as electric signals between the connected constituent elements can be sent and received. Examples of “the element with the certain electric action” include not only an electrode and wire, but also a switching element such as a transistor, or a resistor, an inductor, or a capacitor, or other functional elements.

“Parallel” herein refers to a state in which an angle formed by two straight lines is greater than -10° and less than 10°, and thus also includes a state in which the angle is greater than -5° and less than 5°. In addition, “vertical” refers to a state in which an angle formed by two straight lines is greater than 80° and less than 100°, and thus also includes a state in which the angle is greater than 85° and less than 95°.

“Film” and “layer” herein may be interchangeable. For example, sometimes “conducting layer” may be replaced by “conducting film”. Similarly, sometimes “insulating film” may be replaced by “insulating layer”.

“About” herein means that a boundary is defined loosely and numerical values in process and measurement error ranges are allowed.

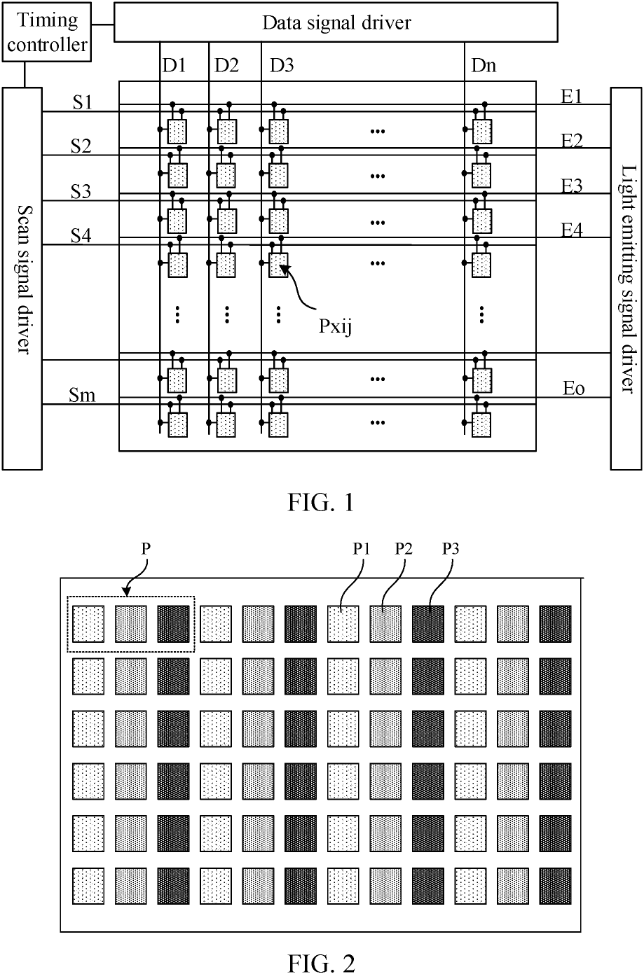

FIG. 1 is a schematic diagram of a structure of an OLED display device. Referring to FIG. 1, the OLED display device may include a timing controller, a data signal driver, a scan signal driver, a light emitting signal driver and a pixel array. The pixel array may include a plurality of scan signal lines (S1 to Sm), a plurality of data signal lines (D1 to Dn), a plurality of light emitting signal lines (E1 to Eo) and a plurality of sub-pixels Pxij. In an exemplary implementation, the timing controller may provide gray scale values and control signals suitable for specifications of the data signal driver to the data signal driver, may provide clock signals and scan start signals suitable for specifications of the scan signal driver to the scan signal driver, and may provide clock signals and emitting stop signals suitable for specifications of the light emitting signal driver to the light emitting signal driver. The data signal driver may use the gray scale values and the control signals received from the timing controller to generate data voltages, which will be provided to the data signal lines D1, D2, D3, ..., Dn,. For example, the data signal driver may sample the gray scale values using the clock signals, and apply the data voltages corresponding to the gray scale values to the data signal lines D1 through Dn by taking a sub-pixel row as a unit, wherein n may be a natural number. The scan signal driver may generate scan signals by receiving the clock signals and the scan start signals from the timing controller, the generated can signal will be provided to the scan signal lines S1, S2, S3, ..., Sm. For example, the scan signal driver may provide sequentially the scan signals with turn-on level pulses to the scan signal lines S1 through Sm. For example, the scan signal driver may be constructed in a form of a shift register, and may generate the scan signals by transmitting sequentially the scan start signals provided in a form of a turn-on level pulse to a next-stage circuit under the control of the clock signals. Herein, m may be a natural number. The light emitting signal driver may generate the light emitting signals by receiving the clock signals and the emitting stop signals from the timing controller, the light emitting signals will be provided to the light emitting signal lines E1, E2, E3, ..., Eo. For example, the light emitting signal driver may provide sequentially the light emitting signals with cut-off level pulses to the light emitting signal lines E1 through Eo. For example, the light emitting signal driver may be constructed in a form of a shift register, and may generate the light emitting signals by transmitting sequentially the light emitting stop signals provided in a form of a cut-off level pulse to a next-stage circuit under the control of the clock signals. Herein, o may be a natural number. The pixel array may include the plurality of sub-pixels PXij. Each of the sub-pixels PXij may be connected to the corresponding data signal line, the corresponding scan signal line and the corresponding light emitting signal line, wherein i and j may be natural numbers. The sub-pixel PXij may refer to a sub-pixel in which a transistor is connected to an i^{th} scan signal line and a j^{th} data signal line.

FIG. 2 is a schematic diagram of a planar structure of a display substrate. In an exemplary implementation, the display substrate may include a display area and a border area located at the periphery of the display area. As shown in FIG. 2, the display area of the display substrate may include a plurality of pixel units P arranged in a matrix. At least one of the plurality of pixel units P includes a first sub-pixel P1 emitting light of a first color, a second sub-pixel P2 emitting light of a second color and a third sub-pixel P3 emitting light of a third color. The first sub-pixel P1, the second sub-pixel P2 and the third sub-pixel P3 each include a pixel driving circuit and a light emitting device. The pixel driving circuits in the first sub-pixel P1, the second sub-pixel P2 and the third sub-pixel P3 are connected to scan signal lines, data signal lines, and light emitting signal lines respectively. The pixel driving circuits are configured to receive data voltages transmitted by the data signal lines and output corresponding currents to the light emitting devices, under the control of the scan signal lines and the light emitting signal lines. The light emitting devices in the first sub-pixel P1, the second sub-pixel P2 and the third sub-pixel P3 are connected respectively to the pixel driving circuits of the sub-pixels in which the light emitting devices are located, and the light emitting devices are configured to emit light of corresponding luminance in response to the currents output by the pixel driving circuits of the sub-pixels in which the light emitting devices are located.

In an exemplary implementation, the pixel unit P may include red (R) sub-pixels, green (G) sub-pixels and blue (B) sub-pixels, or may include red sub-pixels, green sub-pixels, blue sub-pixels and white sub-pixels, which is not limited herein in the present disclosure. In an exemplary implementation, shapes of the sub-pixels in the pixel unit may be a rectangle, a rhombus, a pentagon, or a hexagon. When the pixel unit includes three sub-pixels, the three sub-pixels may be arranged in parallel horizontally, in parallel vertically, or in a shape of an equilateral triangle; when the pixel unit includes four sub-pixels, the four sub-pixels may be arranged in parallel horizontally, in parallel vertically, or in a shape of a square, which is not limited herein in the present disclosure.

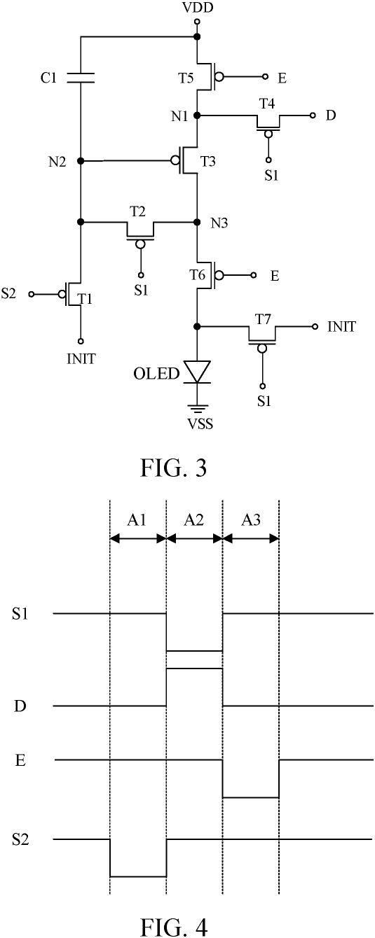

In an exemplary implementation, the pixel driving circuit may have a 3T1C, 4T1C, 5T1C, 5T2C, 6T1C or 7T1C structure. FIG. 3 is a schematic diagram of an equivalent circuit of a pixel driving circuit. As shown in FIG. 3, the pixel driving circuit may include seven transistors (a first transistor T1 through a seventh transistor T7), one storage capacitor C1 and seven signal lines (a data signal line D, a first scan signal line S1, a second scan signal line S2, a light emitting signal line E, an initial signal line INIT, a first power line VDD and a second power line VSS).

In an exemplary implementation, a first end of the storage capacitor C1 is connected to the first power line VDD, and a second end of the storage capacitor C1 is connected to a second node N2, that is, the second end of the storage capacitor C1 is connected to a control electrode of the third transistor T3.

A control electrode of the first transistor T1 is connected to the second scan signal line S2, a first electrode of the first transistor T1 is connected to the initial signal line INIT, and a second electrode of the first transistor is connected to the second node N2. When a turn-on level scan signal is applied to the second scan signal line S2, the first transistor T1 transmits an initial voltage to the control electrode of the third transistor T3 to initialize the quantity of electric charge of the control electrode of the third transistor T3.

A control electrode of the second transistor T2 is connected to the first scan signal line S1, a first electrode of the second transistor T2 is connected to the second node N2, and a second electrode of the second transistor T2 is connected to a third node N3. When a turn-on level scan signal is applied to the first scan signal line S1, the second transistor T2 allow the control electrode of the third transistor T3 to be connected to the second electrode of the third transistor T3.

The control electrode of the third transistor T3 is connected to the second node N2, that is, the control electrode of the third transistor T3 is connected to the second end of the storage capacitor C1, a first electrode of the third transistor T3 is connected to a first node N1, and a second electrode of the third transistor T3 is connected to the third node N3. The third transistor T3 may be referred to as a driving transistor, and the third transistor T3 determines the amount of drive current flowing between the first power line VDD and the second power line VSS according to a potential difference between its control electrode and first electrode.

A control electrode of the fourth transistor T4 is connected to the first scan signal line S1, a first electrode of the fourth transistor T4 is connected to the data signal line D, and a second electrode of the fourth transistor T4 is connected to the first node N1. The fourth transistor T4 may be referred to as a switching transistor, a scanning transistor, etc. When the turn-on level scan signal is applied to the first scan signal line S1, the fourth transistor T4 inputs a data voltage of the data signal line D to the pixel driving circuit.

A control electrode of the fifth transistor T5 is connected to the light emitting signal line E, a first electrode of the fifth transistor T5 is connected to the first power line VDD, and a second electrode of the fifth transistor T5 is connected to the first node N1. A control electrode of the sixth transistor T6 is connected to the light emitting signal line E, a first electrode of the sixth transistor T6 is connected to the third node N3, and a second electrode of the sixth transistor T6 is connected to a first electrode of the light emitting device. The fifth transistor T5 and the sixth transistor T6 may be referred to as light emitting transistors. When a turn-on level light emitting signal is applied to the light emitting signal line E, the fifth transistor T5 and the sixth transistor T6 cause the light emitting device 103 to emit light by forming a drive current path between the first power line VDD and the second power line VSS.

A control electrode of the seventh transistor T7 is connected to the first scan signal line S1, a first electrode of the seventh transistor T7 is connected to the initial signal line INIT, and a second electrode of the seventh transistor T7 is connected to the first electrode of the light emitting device. When the turn-on level scan signal is applied to the first scan signal line S1, the seventh transistor T7 transmits the initial voltage to the first electrode of the light emitting device to initialize the quantity of electric charge accumulated in the first electrode of the light emitting device or release the quantity of electric charge accumulated in the first electrode of the light emitting device.

In an exemplary implementation, a second electrode of the light emitting device is connected to the second power line VSS, signals of the second power line VSS are low-level signals and signals of the first power line VDD are high-level signals continuously provided. The first scan signal line S1 is a scan signal line in a pixel driving circuit in the current display row, and the second scan signal line S2 is a scan signal line in a pixel driving circuit in the previous display row. That is, for the n^{th} display row, the first scan signal line S1 is S(n), the second scan signal line S2 is S(n-1), and the second scan signal line S2 in the current display row and the first scan signal line S1 in the pixel driving circuit in the previous display row are the same signal line, so that signal lines of a display panel can be reduced, thereby implementing a narrow border of the display panel.

In an exemplary implementation, the first transistor T1 through the seventh transistor T7 may be P-type transistors or may be N-type transistors. By using the same type of transistors in the pixel driving circuit, the process flow can be simplified, the process difficulty of the display panel is reduced and the product yield rate is improved. In some possible implementations, the first transistor T1 through the third transistor T3 may include P-type transistors and N-type transistors.

In an exemplary implementation, the first scan signal line S1, the second scan signal line S2, the light emitting signal line E, the initial signal line INIT extend along a horizontal direction, and the second power line VSS, the first power line VDD and the data signal line D extend along a vertical direction.

In an exemplary implementation, the light emitting device may be an organic light emitting diode (OLED) including a first electrode (anode), an organic light emitting layer and a second electrode (cathode) which are stacked.

FIG. 4 is a working sequence diagram of a pixel driving circuit. Exemplary embodiments of the present disclosure will be described below through a working process of the pixel driving circuit shown in FIG. 3. The pixel driving circuit in FIG. 3 includes seven transistors (the first transistor T1 through the seventh transistor T7), one memory capacitor C1, and seven signal lines (the data signal line D, the first scan signal line S1, the second scan signal line S2, the light emitting signal line E, the initial signal line INIT, the first power line VDD, and the second power line VSS). All of the seven transistors are P-type transistors.

In an exemplary implementation, the working process of the pixel driving circuit may include the following stages.

In a first stage A1, which is referred to as a reset stage, signals of the second scan signal line S2 are low-level signals, and signals of the first scan signal line S1 and the light emitting signal line E are high-level signals. The signals of the second scan signal line S2 are low-level signals to cause the first transistor T1 to be turned on, and signals of the initial signal line INIT are provided to the second node N2 to initialize the storage capacitor C1 to clear the original data voltage in the storage capacitor. The signals of the first scan signal line S1 and the light emitting signal line E are high-level signals to cause the second transistor T2, the fourth transistor T4, the fifth transistor T5, the sixth transistor T6 and the seventh transistor T7 to be turned off, thus the OLED will not emit light in this stage.

In a second stage A2, which is referred to as a data writing stage or a threshold compensation stage, the signals of the first scan signal line S1 are low-level signals, the signals of the second scan signal line S2 and the light emitting signal line E are high-level signals, and the data signal line D outputs a data voltage. In this stage, since a second end of the storage capacitor C1 is at a low level, the third transistor T3 is turned on. The signals of the first scan signal line S1 are low-level signals to cause the second transistor T2, the fourth transistor T4 and the seventh transistor T7 to be turned on. The second transistor T2 and the fourth transistor T4 are turned on, so that the data voltage output by the data signal line D is provided to the second node N2 through the first node N1, the turned-on third transistor T3, the third node N3 and the turned-on second transistor T2, and a difference between the data voltage output by the data signal line D and a threshold voltage of the third transistor T3 is charged into the storage capacitor C1. A voltage of the second end (the second node N2) of the storage capacitor C1 is Vd - |Vth|, Vd is the data voltage output by the data signal line D, and Vth is the threshold voltage of the third transistor T3. The seventh transistor T7 is turned on, so that an initial voltage of the initial signal line INIT is provided to a first electrode of the OLED to initialize (reset) the first electrode of the OLED to clear its internal pre-stored voltage, so as to complete the initialization, thereby ensuring that the OLED will not emit light. The signals of the second scan signal line S2 are high-level signals to cause the first transistor T1 to be turned off. The signals of the light emitting signal line E are high-level signals to cause the fifth transistor T5 and the sixth transistor T6 to be turned off.

In a third stage A3, which is referred to as a light emitting stage, the signals of the light emitting signal line E are low-level signals, and the signals of the first scan signal line S1 and the second scan signal line S2 are high-level signals. The signal of the light emitting signal line E are low-level signals to cause the fifth transistor T5 and the sixth transistor T6 to be turned on, and a supply voltage output by the first power line VDD cause a drive voltage to be provided to the first electrode of the OLED through the turned-on fifth transistor T5, third transistor T3 and sixth transistor T6 to drive the OLED to emit light.

In a driving process of the pixel driving circuit, a drive current flowing through the third transistor T3 (driving transistor) is determined by a voltage difference between its gate electrode and first electrode. Since a voltage of the second node N2 is Vdata-|Vth|, the drive current of the third transistor T3 is:

$$\begin{matrix}\text{I} = \text{K*} {\left(\text{Vgs-Vth}\right)}^{2} = \text{K*} {\left[\left(\text{Vdd-Vd+} \left|\text{Vth}\right|\right) \text{-Vth}\right]}^{2} = \\ \text{K*} {\left[\left(\text{Vdd-Vd}\right)\right]}^{2} ,\end{matrix}$$

wherein I is the drive current flowing through the third transistor T3, that is, the drive current driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the supply voltage output by the first power line VDD.

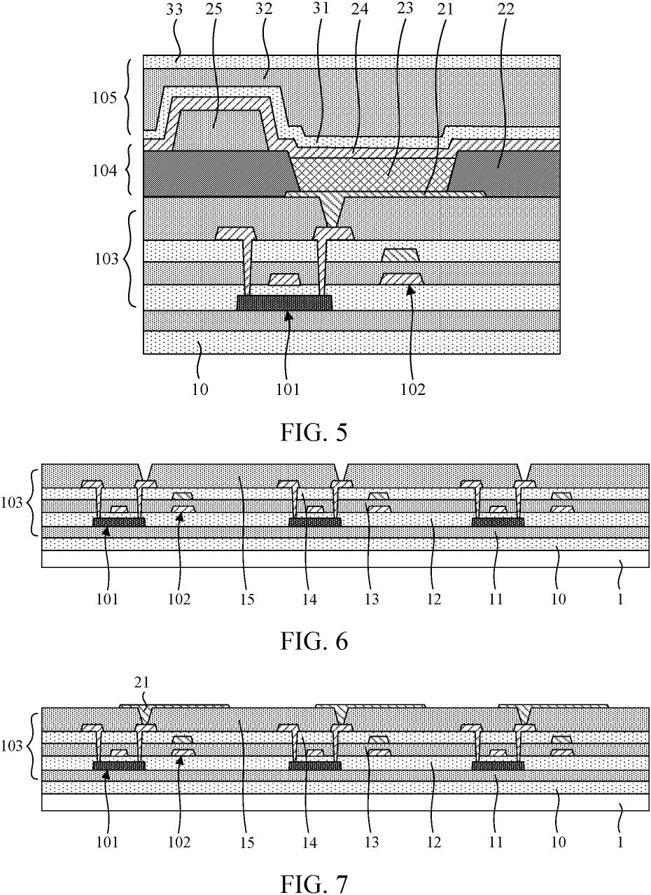

FIG. 5 is a schematic diagram of a sectional structure of a display substrate in accordance with an exemplary embodiment of the present disclosure, which illustrates a structure of a sub-pixel in the display substrate of the OLED. As shown in FIG. 5, in a plane perpendicular to the display substrate, the display substrate may include a driving circuit layer 103 disposed on a substrate 10, a light emitting structure layer 104 disposed at one side of the driving circuit layer 103 away from the substrate 10, and an encapsulation structure layer 105 disposed at one side of the light emitting structure layer 104 away from the substrate 10. In an exemplary implementation, the driving circuit layer 103 may include a transistor 101 and a storage capacitor 102. In an exemplary implementation, the light emitting structure layer 104 is a light emitting device that causes organic materials to emit light. The light emitting structure layer 104 may include an anode 21, a pixel define layer 22, an organic light emitting layer 23, a cathode 24, and a post spacer 25. Pixel openings, which expose the anode 21, are provided in the pixel define layer 22, the organic light emitting layer 23 is arranged between the anode 21 and the cathode 24, the post spacer 25 is arranged on a surface of the pixel define layer 22 at one side away from the substrate 10, and an orthographic projection of the post spacer 25 on the substrate is within an orthographic projection of the pixel define layer 22 on the substrate. In an exemplary implementation, the post spacer (such as Photo spacer (PS)) 25 is configured to support a fine metal mask or an open mask, which is used in evaporating organic luminescent materials. The encapsulation structure layer 105 may include a first encapsulation layer disposed at one side of the light emitting structure layer 104 away from the substrate, a second encapsulation layer disposed at one side of the first encapsulation layer away from the substrate, and a third encapsulation layer disposed at one side of the second encapsulation layer away from the substrate. The second encapsulation layer of an organic material is disposed between the first encapsulation layer and the third encapsulation layer of inorganic materials, to form a stacked structure of inorganic material/organic material/inorganic material.

In an exemplary implementation, materials of the post spacer 25 may include polymer elastomers and nanoparticles. Materials of the polymer elastomers may include polyurethane, polysiloxane and liquid crystal block polymer. The nanoparticles may be inorganic nanoparticles, which may be methyl modified inorganic nanoparticles, which may include methyl modified inorganic silicon oxide nanoparticles, methyl modified inorganic zinc oxide nanoparticles or methyl modified inorganic zirconium oxide nanoparticles.

In an exemplary implementation, methyl modified inorganic nanoparticles can introduce methyl groups to the surface of the inorganic nanoparticles in a manner of processing surfactants.

In an exemplary implementation, the appearance of the polymer elastomers is a cross-linked network, and the inorganic nanoparticles are dispersed in meshes of the cross-linked network formed by the polymer elastomers to support the cross-linked network, which is formed by chemical connection of the polymer elastomers.

In an exemplary implementation, the diameters of the inorganic nanoparticles may be about 20 nm to 100 nm.

In an exemplary implementation, the weight percent of the inorganic nanoparticles in the post spacer may be about 0.5 wt% to 5 wt%.

In an exemplary implementation, the thickness of the post spacer 25 may be about 1.0 µm to 1.5 µm.

A process of manufacturing the display substrate will be described exemplarily below. “Patterning processes” mentioned in the present disclosure include photoresist coating, mask exposure, development, etching, photoresist stripping, etc., for metal materials, inorganic materials or transparent conducting materials, and include organic material coating, mask exposure, development, etc., for organic materials. Deposition may be any one or more of sputtering, evaporation and chemical vapor deposition, coating may be any one or more of spray coating, spin coating and inkjet printing, and etching may be any one or more of dry etching and wet etching, which are not limited in the present disclosure. “Film” refers to a layer of film formed by a certain material on a substrate using deposition, or other processes. If the “film” does not need the patterning processes in the entire manufacturing process, the “film” may also be called a “layer”. If the “film” needs the patterning processes in the entire manufacturing process, the “film” is called a “film” before the patterning processes are performed and is called a “layer” after the patterning processes are performed. The “layer” processed by the patterning processes includes at least one “pattern”. “A and B being disposed on the same layer” mentioned in the present disclosure means that A and B are formed simultaneously through the same running of the patterning processes, and the “thickness” of the film layer is the size of the film layer in a direction perpendicular to the display substrate. In an exemplary embodiment of the present disclosure, “an orthographic projection of B is within an orthographic projection of A” means that the boundary of the orthographic projection of B falls within the boundary of the orthographic projection of A, or the boundary of the orthographic projection of A is overlapped with the boundary of the orthographic projection of B.

In an exemplary implementation, the process of manufacturing the display substrate includes the following operations.

A substrate is formed on a glass carrier plate. In an exemplary implementation, forming the substrate on the glass carrier plate may include: coating a first flexible material film on the glass carrier plate 1 to form a first flexible layer after it is cured into a film; coating a second flexible material film on a surface of the first flexible layer at one side away from the glass carrier plate, to form a second flexible layer after it is cured into a film; and coating a third flexible material film on a surface of the second flexible layer at one side away from the glass carrier plate, to form a third flexible layer after it is cured into a film, and form the flexible substrate on the glass carrier plate. The substrate includes the first flexible layer, the second flexible layer and the third flexible layer which are stacked. In an exemplary implementation, the first flexible layer, the second flexible layer and the third flexible layer may be made of the same materials or different materials. In some possible embodiments, the materials of the first flexible layer, the second flexible layer and the third flexible layer may include polyimide (PI).

In another exemplary implementation, forming the substrate on the glass carrier plate 1 may include: firstly coating the first flexible material film on the glass carrier plate, to form the first flexible layer after it is cured into a film; then depositing a first inorganic material film on the first flexible layer to form a first inorganic layer overlying the first flexible layer; then depositing the second flexible material film on the first inorganic layer to form the second flexible layer after it is cured into a film; and then depositing a second inorganic material film on the second flexible layer, to form a second inorganic layer overlying the second flexible layer, and form the flexible substrate on the glass carrier plate. The substrate includes the first flexible layer, the first inorganic layer, the second flexible layer and the second inorganic layer which are stacked. In an exemplary implementation, materials of the first and second flexible material film may be polyimide (PI), polyethylene terephthalate (PET), pressure sensitive adhesive (PSA) or surface-treated polymer soft film, and materials of the first and second inorganic material film may be silicon nitride (SiNx) or silicon oxide (SiOx) for improving the water and oxygen resistance of the substrate. The first and second inorganic layer are called first and second barrier layer.

In yet another exemplary implementation, forming the substrate on the glass carrier plate 1 may include: firstly coating the first flexible material film on the glass carrier plate, to form the first flexible layer after it is cured into a film; then depositing the first inorganic material film on the first flexible layer to form the first inorganic layer overlying the first flexible layer; then depositing an amorphous silicon film on the first inorganic layer to form an amorphous silicon layer overlying the first inorganic layer; then coating the second flexible material film on the amorphous silicon layer, to form the second flexible layer after it is cured into a film; and then depositing the second inorganic material film on the second flexible layer, to form the second inorganic layer overlying the second flexible layer, and form the flexible substrate on the glass carrier plate. The substrate includes the first flexible layer, the first inorganic layer, a semiconductor layer, the second flexible layer and the second inorganic layer which are stacked. In an exemplary implementation, a material of the semiconductor layer may be amorphous silicon (a-si).

In an exemplary implementation, the substrate may be a rigid substrate.

A pattern of a driving structure layer is formed on the substrate, as shown in FIG. 6. In an exemplary implementation, the driving structure layer may include a plurality of transistors and storage capacitors forming a pixel driving circuit. Three sub-pixels are illustrated in FIG. 6. The driving structure layer of each sub-pixel is illustrated by taking one transistor 101 and one storage capacitor 102 as an example. In an exemplary implementation, a process of manufacturing the driving structure layer may include the following operations.

A first insulating film and a semiconductor layer film are deposited sequentially on the substrate 10, and the semiconductor layer film is patterned through the patterning processes to form a first insulating layer 11 overlying the entire substrate 10 and form a pattern of a semiconductor layer disposed on the first insulating layer 11. The pattern of the semiconductor layer at least includes an active layer disposed in each sub-pixel.

Then, a second insulating film and a first metal film are deposited sequentially, and the first metal film is patterned through the patterning processes to form a second insulating layer 12 overlying the pattern of the semiconductor layer and form a pattern of a first metal layer disposed on the second insulating layer 12. The pattern of the first metal layer at least includes a gate electrode and a first capacitor electrode disposed in each sub-pixel.

Then, a third insulating film and a second metal film are deposited sequentially, and the second metal film is patterned through the patterning processes to form a third insulating layer 13 overlying the first metal layer and form a pattern of a second metal layer disposed on the third insulating layer 13. The pattern of the second metal layer pattern at least include a second capacitor electrode disposed in each sub-pixel, and a position of the second capacitor electrode corresponds to that of the first capacitor electrode.

Then, a fourth insulating film is deposited, the fourth insulating film is patterned through the patterning processes to form a pattern of a fourth insulating layer 14 overlying the second metal layer, and patterns of a plurality of via holes are provided in the fourth insulating layer 14. The patterns of the plurality of via holes at least include two first via holes in each sub-pixel, and positions of the two first via holes correspond respectively to positions of two ends of the active layer. The fourth insulating layer 14, the third insulating layer 13 and the second insulating layer 12 in the two first via holes are etched away to expose the surface of the active layer.

Then, a third metal film is deposited, and the third metal film is patterned through the patterning processes to form a pattern of a third metal layer on the fourth insulating layer 14. The pattern of the third metal layer at least include a source electrode and a drain electrode disposed in each sub-pixel, and the source electrode and the drain electrode are connected respectively to the active layer of the sub-pixel through the first via holes, so that a conducting channel is formed between the source electrode and the drain electrode.

Then, a planarization film is coated to form a planarization (PLN) layer 15 overlying the entire substrate 10, and patterns of the via holes are formed through the patterning processes on the planarization layer 15, the patterns of the via holes at least includes second via holes disposed in each sub-pixel, and the planarization layer 15 in the second via holes is removed to expose the surface of the drain electrode. In an exemplary implementation, the surface of the planarization layer 15 at one side away from the substrate 10 is a flat surface, and the planarization layer may be made of a material such as resin.

So far, the formed structure includes the substrate 10 disposed on the glass carrier plate 1 and the driving structure layer 103 disposed on the substrate 10, as shown in FIG. 6. The active layer, the gate electrode, the source electrode and the drain electrode in each sub-pixel form the transistor 101. The first capacitor electrode and the second capacitor electrode form the storage capacitor 102. In an exemplary implementation, the transistor may be a driving transistor in the pixel driving circuit, and the driving transistor may be a film transistor.

In an exemplary implementation, the first insulating layer, the second insulating layer, the third insulating layer and the fourth insulating layer may be made of any one or more of silicon oxide (SiOx), silicon nitride (SiNx) and silicon oxynitride (SiON), and may be a single layer, multiple layers or a composite layer. The first insulating layer is referred to as a buffer layer for improving the water and oxygen resistance of the substrate, the second insulating layer and the third insulating layer are referred to as gate insulating (GI) layers, the fourth insulating layer is referred to as an interlayer dielectric (ILD) layer. The planarization film may be made of an organic material, such as resin. The first metal film, the second metal film and the third metal film may be made of metal materials, such as any one or more of silver (Ag), copper (Cu), aluminum (Al), titanium (Ti) and molybdenum (Mo), or alloy materials of the aforementioned metals, such as aluminum neodymium alloy (AlNd) or molybdenum niobium alloy (MoNb), and may be a single-layered structure or a multi-layered composite structure, such as Ti/Al/Ti, etc. The active layer film may be made of various materials, such as amorphous indium gallium zinc oxide (a-IGZO), zinc oxynitride (ZnON), indium zinc tin oxide (IZTO), amorphous silicon (a-Si), polycrystalline silicon (p-Si), sexithiophene, and polythiophene, that is, the present disclosure is applicable to transistors manufactured based on oxide technology, silicon technology and organic matter technology.

A pattern of an anode is formed. In an exemplary implementation, forming the pattern of the anode may include: depositing a conducting film on the substrate, on which aforementioned patterns are formed, and patterning the conducting film through the patterning processes to form a pattern of a conducting layer. The pattern of the conducting layer at least include the anode 21 disposed in each sub-pixel, and the anode 21 is connected to the drain electrode of the first transistor 101 through the second via holes, as shown in FIG. 7.

In an exemplary implementation, the conducting film may be made of a single layer of transparent conducting material, such as indium tin oxide (ITO) or indium zinc oxide (IZO), or the conducting film may be made of a composite layer of a metal material and a transparent conducting material, such as Ag/ITO, Ag/IZO or ITO/Ag/ITO. The thickness of the metal material in the composite layer may be about 80 nm to 100 nm, and the thickness of the transparent conducting material in the composite layer may be about 5 nm to 20 nm, so that the average reflectivity of the anode in the visible light region is about 85%-95%.

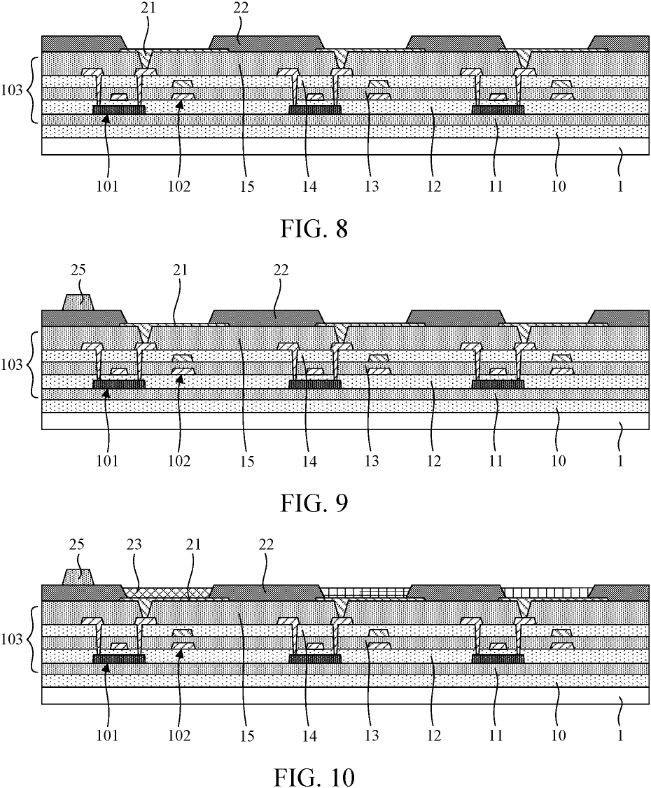

A pattern of a pixel define layer is formed. In an exemplary implementation, forming the pattern of the pixel define layer may include: coating a pixel define film on the substrate, on which aforementioned patterns are formed, and performing mask exposure and development for the pixel define film through the patterning processes to form the pixel define layer (PDL) 22. Pixel openings are provided in the pixel define layer 22 in each sub-pixel, and the pixel define film in the pixel openings is developed away to expose the surface of the anode 21, as shown in FIG. 8.

In an exemplary implementation, the thickness of the pixel define layer may be about 1 µm to 1.5 µm.

In an exemplary implementation, in a direction parallel to the substrate, the shape of the pixel openings may be a square, a rectangle, a circle, an ellipse or a hexagon, and may be set according to the actual needs, which is not limited in the present disclosure. In the exemplary implementation, the pixel define film may be made of a material such as polyimide, acrylic, or polyethylene terephthalate.

A pattern of a post spacer is formed. In an exemplary implementation, forming the pattern of the post spacer may include: coating a post spacer film on the substrate, on which aforementioned patterns are formed, and patterning the post spacer film through the patterning processes to form the pattern of the post spacer 25. The post spacer 25 is arranged on the surface of the pixel define layer 22 at one side away from the substrate, and an orthographic projection of the post spacer 25 on the substrate is within an orthographic projection of the pixel define layer 22 on the substrate, as shown in FIG. 9.

In an exemplary implementation, for a plurality of pixel units on the display substrate, at least one post spacer may be arranged in at least one pixel unit containing an R sub-pixel, a G sub-pixel and a B sub-pixel. A plurality of post spacers in a display area can be distributed evenly, a plurality of post spacers in a border area can be arranged in an area within a boundary of an encapsulation layer, and no post spacer is arranged in areas outside the boundary of the encapsulation layer.

In an exemplary implementation, materials of the post spacer may include polymer elastomers and inorganic nanoparticles. Materials of the polymer elastomers may include polyurethane, polysiloxane and liquid crystal block polymer. The inorganic nanoparticles may be methyl modified inorganic nanoparticles, which may include methyl modified inorganic silicon oxide nanoparticles, methyl modified inorganic zinc oxide nanoparticles or methyl modified inorganic zirconium oxide nanoparticles. The appearance of the polymer elastomers is a cross-linked network formed by chemical connection, and the inorganic nanoparticles are dispersed in meshes of the cross-linked network formed by the polymer elastomers to support the cross-linked network.

In an exemplary implementation, the molecular weight of the polymer elastomers may be on the order of about one million to ten million, the refractive index of the polymer elastomers may be about 1.5 to 1.7, and the diameters of the meshes of the cross-linked network may be about 0.5 µm to 2.0 µm.

In an exemplary implementation, methyl modified inorganic nanoparticles can introduce methyl groups to the surface of the inorganic nanoparticles in a manner of processing surfactants.

In an exemplary implementation, the diameters of the inorganic nanoparticles may be about 20 nm to 100 nm.

In an exemplary implementation, the weight percent of the inorganic nanoparticles may be about 0.5 wt% to 5 wt% of the post spacer, and the inorganic nanoparticles may be distributed in the polymer elastomers evenly.

In the plane parallel to the substrate, the shape of the post spacer may be a square, a rectangle, a circle, an ellipse or a hexagon. For the rectangular post spacer, the width of the post spacer may be about 5 µm to 10 µm.

In an exemplary implementation, the height of the post spacer may be 1 µm to 1.5 µm.

In a plane perpendicular to the substrate, the sectional shape of the post spacer may be a trapezoid, a base angle of the trapezoid may be about 40° to 60°.

In an exemplary implementation, the coating of the post spacer film and the patterning processes can be performed in the following manner. Firstly, the polymer elastomers, inorganic nanoparticles and a photosensitizer are mixed to form a colloidal sol, then the colloidal sol is coated evenly on the substrate, on which aforementioned patterns are formed, to form the post spacer film, and the pattern of the post spacer is formed by a local ultraviolet light curing process after the post spacer film is exposed and developed using a post spacer mask.

In an exemplary implementation, the post spacer mask includes a light transmission area and an opaque area, and the photosensitizer is a negative photosensitizer. After the post spacer film is exposed, the post spacer film corresponding to the position of the light transmission area of the post spacer mask forms a fully exposed area, and the post spacer film corresponding to the position of the opaque area of the post spacer mask forms an unexposed area. The post spacer film in the fully exposed area is retained after the development, to form the pattern of the post spacer, and the post spacer film in the unexposed area is removed completely.

A pattern of an organic light emitting layer is formed. In an exemplary implementation, forming the pattern of the organic light emitting layer may include: providing an evaporation mask on the substrate, on which aforementioned patterns are formed, and forming the pattern of the organic light emitting layer 13 through the evaporation process. The organic light emitting layer 23 is connected to the anode 21 in the pixel openings, as shown in FIG. 10.

In an exemplary implementation, the organic light emitting layer may include a light emitting layer (EML) and any one or more of: a hole injection layer (HIL), a hole transport layer (HTL), an electron block layer (EBL), a hole block layer (HBL), an electron transport layer (ETL), and an electron injection layer (EIL). In an exemplary implementation, the light emitting layers of different sub-pixels are different. For example, a red sub-pixel includes a red light emitting layer, a green sub-pixel includes a green light emitting layer, and a blue sub-pixel includes a blue light emitting layer.

In an exemplary implementation, the organic light emitting layer may be formed by evaporation using a fine metal mask (FMM) or an open mask, or formed by an inkjet process. Although the organic light emitting layers of a plurality of sub-pixels illustrated in the drawings are isolated from each other, in an exemplary implementation, in order to decrease the process difficulty and improve the yield rate, the hole injection layer and the hole transport layer located at one side of the light emitting layer may be a common layer respectively, and the electron injection layer and the electron transport layer located at the other side of the light emitting layer may be a common layer respectively. In an exemplary implementation, any one or more of the hole injection layers, the hole transport layers, the electron injection layers and the electron transport layers may be manufactured by one running of the processes (one running of the evaporation process or one running of the inkjet printing process), but the isolation is implemented by means of the height difference of the formed film layer or by means of surface treatment. For example, any one or more of the hole injection layers, the hole transport layers, the electron injection layers and the electron transport layers corresponding to adjacent sub-pixels may be isolated.

In an exemplary implementation, the organic light emitting layer may be manufactured by the following manufacture method. After the manufacturing of the post spacer is completed, the hole injection layer and the hole transport layer are formed sequentially by evaporation using the open mask first, and the common layer of the hole injection layer and the hole transport layer is formed on the display substrate, that is, the hole injection layers of all sub-pixels are connected, and the hole transport layers of all sub-pixels are connected. The respective areas of the hole injection layer and the hole transport layer are approximately the same and their thicknesses are different. Then, the electronic block layer and the red light emitting layer, the electronic block layer and the green light emitting layer, and the electronic block layer and the blue light emitting layer are formed respectively by evaporation in different sub-pixels using the fine metal mask. There may be slight overlap between the electron block layers and the light emitting layers of the adjacent sub-pixels (for example, the overlap portion accounts for less than 10% of the area of pattern of the respective light emitting layer), or the electron block layers may be isolated from the light emitting layers. Then, the hole block layer, the electron transport layer, and the electron injection layer are formed sequentially by evaporation using the open mask, and the common layer of the hole block layer, the electron transport layer, and the electron injection layer is formed on the display substrate, that is, the hole block layers of all sub-pixels are connected, the electron transport layers of all sub-pixels are connected, and the electron injection layers of all sub-pixels are connected.

In an exemplary implementation, orthographic projections of one or more of the hole injection layer, the hole transport layer, the hole block layer, the electron transport layer, the electron injection layer, and the cathode on the substrate are continuous. In some examples, at least one layer of the hole injection layer, the hole transport layer, the hole block layer, the electron transport layer, the electron injection layer and the cathode in at least one row or column of sub-pixels is a connected layer. In some examples, at least one layer of the hole injection layer, the hole transport layer, the hole block layer, the electron transport layer, the electron injection layer and the cathode of a plurality of sub-pixels is a connected layer.

In an exemplary implementation, because the hole blocking layer is a common layer and the light emitting layers of different sub-pixels are isolated, an orthographic projection of the light emitting layer on the substrate is within the orthographic projection of the hole block layer on the substrate, and the area of the hole block layer is larger than that of the light emitting layer. Because the hole block layer is a common layer, the orthographic projection of the hole block layer on the substrate at least includes orthographic projections of light emitting areas of two sub-pixels on the substrate. In an exemplary implementation, orthographic projections of the light emitting layers of at least a portion of the sub-pixels on the substrate is overlapped with an orthographic projection of the pixel driving circuit on the substrate.

In an exemplary implementation, the electron block layer may serve as a microcavity adjustment layer between the hole transport layer and the light emitting layer, so that the thickness of the organic light emitting layer between the cathode and the anode can be designed according to requirements for an optical path of an optical micro resonant cavity, to obtain the optimal intensity and color of the emitted light.

In an exemplary implementation, the light emitting layer may include a host material and a dopant material doped into the host material. A doping ratio of the dopant material in the light emitting layer is 1% to 20%. Within the doping ratio, on one hand, the host material in the light emitting layer can be used to effectively transfer exciton energies to the dopant material in the light emitting layer to excite the dopant material in the light emitting layer to emit light; on the other hand, the host material in the light emitting layer is used to “dilute” the dopant material in the light emitting layer, so as to alleviate effectively the collision between molecules of the dopant material in the light emitting layer, and alleviate fluorescence quenching caused by the collision between the energies, improving the luminous efficiency and device life. In an exemplary implementation, the doping ratio refers to a ratio of the mass of the dopant material to the mass of the light emitting layer, that is, a mass percentage. In an exemplary implementation, the host material and the dopant material can be evaporated through a multi-source evaporation process, so that the host material and the dopant material are dispersed in the light emitting layer evenly. The doping ratio may be adjusted by controlling an evaporation rate of the dopant material or by controlling a ratio of an evaporation rate of the host material to an evaporation rate of the dopant material during the evaporation process.

In an exemplary implementation, the hole injection layer may be made of an inorganic oxide, such as molybdenum oxide, titanium oxide, vanadium oxide, rhenium oxide, ruthenium oxide, chromium oxide, zirconium oxide, hafnium oxide, tantalum oxide, silver oxide, tungsten oxide or manganese oxide, or may be made of a p-type dopant of a strong electron absorption system and a dopant of a hole transport material. In an exemplary implementation, the thickness of the hole injection layer may be about 5 nm to 20 nm.

In an exemplary implementation, the hole transport layer may be made of a material with high hole mobility, such as an aromatic amine compound, a substituent group of which may be carbazole, methylfluorene, spirofluorene, dibenzothiophene or furan. In an exemplary implementation, the thickness of the hole transport layer may be about 60 nm to 150 nm.

In an exemplary implementation, the electron block layer may be made of an aromatic amine compound with hole transport characteristics, a substituent group of which may be carbazole, methylfluorene, spirofluorene, dibenzothiophene or furan. In an exemplary implementation, the thickness of the electron block layer may be about 5 nm to 20 nm.

In an exemplary implementation, the light emitting layer may include a luminescent host material and a luminescent dopant material. The luminescent host material may be a bipolar single host, or a double host formed by blending a hole type host and an electronic type host. The luminescent dopant material may be a phosphorescent material, a fluorescent material, a delayed fluorescent material, or the like. In an exemplary implementation, the thickness of the light emitting layer may be about 10 nm to 25 nm.

In an exemplary implementation, the hole block layer and the electron transport layer may be made of aromatic heterocyclic compounds, such as imidazole derivatives such as benzimidazole derivatives, imidazopyridine derivatives, and benzimidazole phenanthridine derivatives; oxazine derivatives such as pyrimidine derivatives and triazine derivatives; compounds having nitrogen-containing hexatomic ring structure (also including compounds having substituent groups of phosphine oxide systems on heterocyclic rings) such as quinoline derivatives, isoquinoline derivatives, phenanthroline derivatives, etc. In an exemplary implementation, the thickness of the hole block layer may be about 5 nm to 15 nm, and the thickness of the electron transport layer may be about 20 nm to 50 nm.

In an exemplary implementation, the electron injection layer may be made of alkali metals or metals such as lithium fluoride (LiF), ytterbium (Yb), magnesium (Mg) or calcium (ca), or compounds of these alkali metals or metals. In an exemplary implementation, the thickness of the electron injection layer may be about 0.5 nm to 2 nm.

Damages to the surface of the post spacer are repaired. In an exemplary implementation, repairing the damages to the surface of the post spacer may include: irradiating the post spacer with ultraviolet light on the substrate, on which aforementioned patterns are formed, to eliminate the damages to the surface of the post spacer.

Because organic materials are easy to react with water and oxygen, OLED display devices have very high requirements for encapsulation. After years of development, the existing film encapsulation methods have been able to basically meet requirements for the flexible OLEDs as a whole regarding to penetration rates of water vapor and oxygen, and have characteristics such as lightness, thinness and bendability. However, in actual production, there is still the problem of failure of encapsulation of the sub-pixels, decreasing the yield rate. It is found in the research that failure of encapsulation of the sub-pixels in actual production is caused by the damages to the surface of the post spacer. Because the organic light emitting layer needs to be formed by evaporation onto the display substrate through the fine metal mask, the post spacer will be fabricated on the display substrate to support the fine metal mask. Generally, the process of forming the organic light emitting layer by evaporation using the fine metal mask includes: firstly aligning the fine metal mask with the first sub-pixel and leaning the fine metal mask against the surface of the post spacer, forming the light emitting layer of the first color by evaporation in the first sub-pixel, and separating the fine metal mask from the post spacer after the evaporation is completed; then aligning the fine metal mask with the second sub-pixel and leaning the fine metal mask against the surface of the post spacer, forming the light emitting layer of the second color by evaporation in the second sub-pixel, and separating the fine metal mask from the post spacer after the evaporation is completed; and then aligning the fine metal mask with the third sub-pixel and leaning the fine metal mask against the surface of the post spacer, forming the light emitting layer of the third color by evaporation in the third sub-pixel, and separating the fine metal mask from the post spacer after the evaporation is completed.

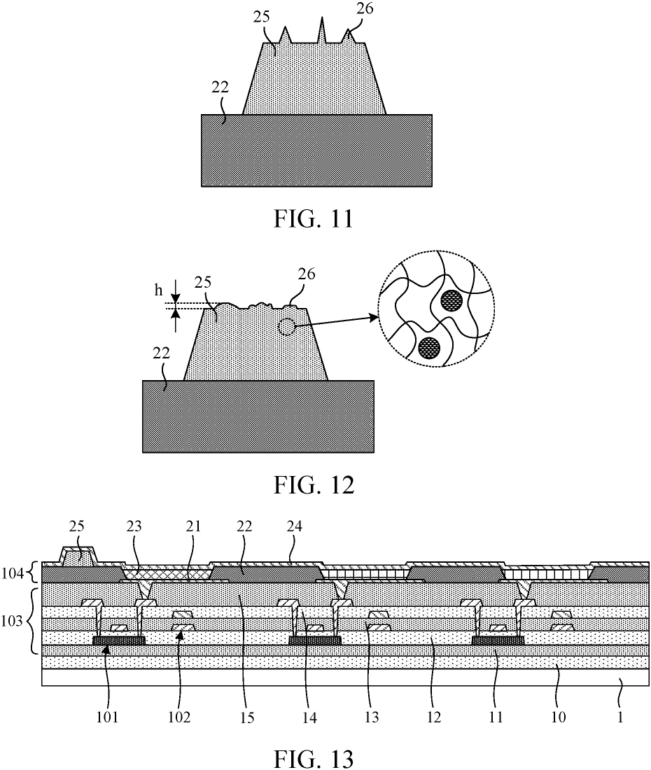

FIG. 11 is a schematic diagram of sharp protrusions occurring on a surface of a post spacer. As shown in FIG. 11, during the alignment process before the evaporation and the separation process after evaporation, there are multiple frictions between the fine metal mask and the post spacer, causing the damages to the surface of the post spacer, such that some sharp protrusions 26 occur on the surface of the post spacer 25. The actual measurement shows that heights of the sharp protrusions can reach 0.5 µm to 1 µm. Because these sharp protrusions are located on the top of the post spacer, i.e., located at one side of the post spacer towards the subsequently formed encapsulation layer, thus these sharp protrusions are easy to pierce the encapsulation layer, so that water and oxygen can penetrate into the organic light emitting layer through breaches, resulting in failure of encapsulation.

FIG. 12 is a schematic diagram of a post spacer after damages to its surface are repaired in accordance with an exemplary embodiment of the present disclosure. In an exemplary implementation, the process of repairing the damages to the surface of the post spacer can be performed in the following manner. Firstly, the post spacer mask of the previously patterned post spacer is provided on the display substrate, and the manner of aligning the post spacer mask is the same as the manner of aligning in the post spacer patterning, that is, the position of the light transmission area in the post spacer mask corresponds to the position of the post spacer in the display substrate. Then, the post spacer is irradiated using an ultraviolet light device, the ultraviolet light passing through the light transmission area of the post spacer mask to irradiate the post spacer. Because expansion and contraction of the cross-linked network of the polymer elastomers will occur under the irradiation of the ultraviolet light, protruding portions are in an expanded state and flat portions are in a contracted state, so that the protrusions on the surface of the post spacer change from sharp to smooth, and their heights are decreased, and the heights h of the smooth protrusions can be decreased to less than 0.2 µm, thereby implementing the repair of the damages to the surface of the post spacer, as shown in FIG. 12.

In an exemplary implementation, the irradiation intensity of the ultraviolet light may be about 5 mW/cm² to 20 mW/cm², and the irradiation time of the ultraviolet light may be about 100 seconds to 300 seconds.

A pattern of a cathode is formed. In an exemplary implementation, forming the pattern of the cathode may include: forming the pattern of the cathode 24 on the substrate, on which aforementioned patterns are formed, through the evaporation process. The cathode 24 is connected to the organic light emitting layer 23, as shown in FIG. 13.

In an exemplary implementation, the cathodes 24 of a plurality of sub-pixels form a planar integrated structure, and the cathodes 24 wrap the surfaces of the post spacers 25.

In an exemplary implementation, the cathode may be made of a metal material, which may be magnesium (Mg), silver (Ag) or aluminum (Al), or an alloy material, such as an alloy of Mg:Ag. The ratio of Mg:Ag is about 9:1 to 1:9, and the thickness of the cathode may be about 10 nm to 20 nm.

So far, the pattern of the light emitting structure layer 104 has been formed on the driving structure layer 103, as shown in FIG. 13. In an exemplary implementation, the anode 21, the organic light emitting layer 23 and the cathode 24 in the light emitting structure layer 104 form a light emitting element of the OLED, and the organic light emitting layer 23 is arranged between the anode 21 and the cathode 24. Holes and electrons are injected into the organic light emitting layer 23 from the anode 21 and the cathode 24, respectively. When the electrons and holes meet in the organic light emitting layer 23, the electrons and holes combine to generate excitons, which give out light while being transformed from the excited state to the ground state. The organic light emitting layer 23 emits light of corresponding grayscale.

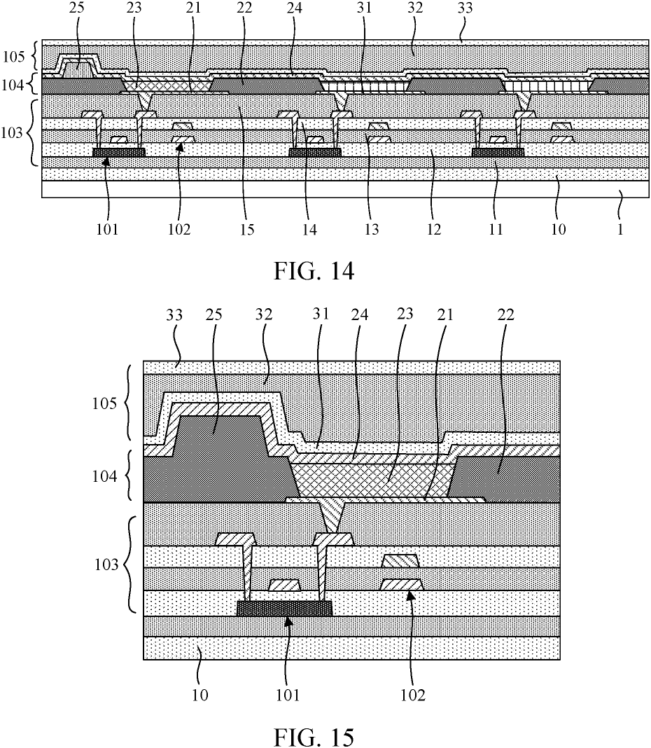

An encapsulation structure layer is formed. In an exemplary implementation, forming the encapsulation structure layer may include: depositing a first inorganic film using the open mask to form a first encapsulation layer 31; then, performing inkjet printing of an organic material on the first encapsulation layer through an inkjet printing process, and forming a second encapsulation layer 32 after it is cured into a film; then, depositing a second inorganic film using the open mask to form a third encapsulation layer 33, as shown in FIG. 14. In an exemplary embodiment, the first encapsulation layer and the third encapsulation layer may be made of any one or more of silicon oxide (SiOx), silicon nitride (SiNx) and silicon oxynitride (SiON), and may be a single layer, multiple layers or a composite layer, and the second encapsulation layer may be made of a resin material.

So far, pattern of the encapsulation structure layer 105 has been formed on the light emitting structure layer 104, as shown in FIG. 14. The encapsulation structure layer 105 may include the first encapsulation layer 31, the second encapsulation layer 32 and the third encapsulation layer 33 which are stacked, so as to form a stacked structure of inorganic material/organic material/inorganic material. The organic material layer is disposed between the two inorganic material layers, so as to ensure that external water vapor cannot enter the light emitting structure layer. In an exemplary embodiment, the thickness of the first encapsulation layer may be about 800 nm to 1200 nm, the thickness of the second encapsulation layer may be about 6000 nm to 10000 nm, and the thickness of the third encapsulation layer may be about 600 nm to 800 nm.

In an exemplary implementation, after the manufacturing of the encapsulation structure layer is completed, a touch structure layer (TSP) may be formed on the encapsulation structure layer. The touch structure layer may include a touch electrode layer, or include a touch electrode layer and a touch insulating layer. In an exemplary implementation, during the manufacturing of a flexible display substrate, the process of manufacturing the display substrate may further include processes such as stripping the glass carrier plate 1, attaching a back film and cutting, which is not limited in the present disclosure.

It can be seen from the structure and the manufacturing process thereof in accordance with the exemplary embodiments of the present disclosure that the damages to the surface of the post spacer caused by the fine metal mask are repaired effectively by using the post spacer including the polymer elastomers and the inorganic nanoparticles and repairing the post spacer after the light emitting layer is formed by evaporation, so that the protrusions on the surface of the post spacer change from sharp to smooth, and the heights of the protrusions are greatly decreased, so as to prevent the protrusions from piercing the encapsulation layer, thereby avoiding failure of encapsulation, ensuring effectively the encapsulation effect, eliminating the problem of failure of encapsulation of the sub-pixels, and improving the field rate.

In an exemplary implementation, part of light emitted by the organic light emitting layer is emitted after it is incident to the encapsulation layer through the post spacer. In the display substrate, the post spacer is usually made of organic materials with higher refractive indexes. According to the optical principle, when light is incident from an optically denser medium with a higher refractive index to an optically thinner medium with a lower refractive index, if its incident angle is greater than the total reflection angle relative to an interface between the optically denser medium and the optically thinner medium, the total reflection will occur. Thus, part of light inside the post spacer will be totally reflected at the interface of the post spacer, so that the light will be confined in the post spacer, causing light loss and decreasing the light output efficiency and luminance. According to the present invention, the transmission direction of the light in the post spacer can be changed by using the post spacer including the inorganic nanoparticles and by refraction and/or reflection of the light through the inorganic nanoparticles, such that the total reflection of the light on the interface of the post spacer is eliminated, thereby improving the light output efficiency effectively and increasing the luminance effectively.

In an exemplary implementation, external water and oxygen may permeate into the organic light emitting layer through the post spacer. In the display substrate, the post spacer is usually made of organic materials, and the water and oxygen permeabilities are high, so the ability to block water and oxygen is weak. According to the present invention, due to the stronger ability of the inorganic nanoparticles to block water and oxygen, the ability of the post spacer to block water and oxygen is improved effectively by using the post spacer including the inorganic nanoparticles, such that the probability of external water and oxygen penetrating into the organic light emitting layer through the post spacer is decreased, thereby increasing the service life of the display substrate effectively.

The structure and the manufacturing process thereof in accordance with the exemplary embodiments of the present disclosure are only described exemplarily. In an exemplary implementation, the corresponding structure may be altered and the patterning processes may be increased or decreased according to the actual needs. For example, the transistor in the driving structure layer may be a top gate structure or a bottom gate structure, or may be a single-gate structure or a double-gate structure. As another example, other film layer structures, electrode structures, or lead structures may further be provided in the driving structure layer and the light emitting structure layer. As a further example, the substrate may be a glass substrate, which is not limited specifically in the present disclosure.

FIG. 15 is a schematic diagram of a sectional structure of another display substrate in accordance with an exemplary embodiment of the present disclosure, which illustrates a structure of a sub-pixel in the OLED display substrate. In the direction perpendicular to the display substrate, the display substrate may include a driving circuit layer 103 disposed on the substrate 10, a light emitting structure layer 104 disposed at one side of the driving circuit layer 103 away from the substrate 10, and an encapsulation structure layer 105 disposed at one side of the light emitting structure layer 104 away from the substrate 10. In the exemplary implementation, structures of the driving circuit layer 103 and the encapsulation structure layer 105 in the display substrate of this exemplary embodiment are the same as the previous embodiments, but the difference is that the pixel define layer 22 and the post spacer 25 in the light emitting structure layer 104 of this exemplary embodiment are made of the same material, and can be formed simultaneously through the same running of the patterning processes. As shown in FIG. 15, the light emitting structure layer 104 may include an anode 21, a pixel define layer 22, an organic light emitting layer 23, an cathode 24 and an post spacer 25. The pixel openings exposing the anode 21 are provided in the pixel define layer 22, the organic light emitting layer 23 is arranged between the anode 21 and the cathode 24, and the post spacer 25 are arranged on the pixel define layer 22. Materials of the pixel define layer 22 and the post spacer 25 may include polymer elastomers and inorganic nanoparticles, that is, the materials of the pixel define layer 22 and the post spacer 25 are the same.

In an exemplary implementation, materials and parameters of the polymer elastomer and the inorganic nanoparticles can be the same as the previous embodiments, and will not be repeated herein.

In the process of manufacturing the display substrate in accordance with an exemplary implementation, the processes of forming the substrate, forming the driving structure layer, forming the anode, forming the organic light emitting layer, repairing the damages to the post spacer, forming the cathode and forming the encapsulation structure layer can be the same as the previous embodiments, but the difference is that the pixel define layer and the post spacer can be formed simultaneously through one running of the patterning process in this exemplary embodiment.

In an exemplary implementation, the patterning process which is used to form the pixel define layer and the post spacer simultaneously may include the following processes. Firstly, the polymer elastomers, inorganic nanoparticles and photosensitizer are mixed to form a colloidal sol, and then the colloidal sol is coated evenly on the substrate, on which aforementioned patterns are formed, to form the pixel define film. Subsequently, the pixel define film is exposed using a gray tone mask, to form fully exposed areas, partially exposed areas and unexposed areas after the development. The pixel define film in the fully exposed areas is retained to form the pattern of the post spacer, the thickness of the pixel define film in the partially exposed areas is decreased by removing part of the pixel define film to form the pattern of the pixel define layer, and the pixel define film in the unexposed areas is removed completely to form patterns of the pixel openings.

In an exemplary implementation, when the damages to the post spacer are repaired, the gray tone mask is first provided on the display substrate, the position of the light transmission area (fully exposed area) of the gray tone mask corresponding to the position of the post spacer, and then the post spacer is irradiated using an ultraviolet light device, the ultraviolet light passing through the light transmission area of the gray tone mask to irradiate the post spacer, so as to implement the repair of the damages to the surface of the post spacer.

In the exemplary embodiments of the present disclosure, the damages to the surface of the post spacer caused by the fine metal mask are repaired effectively by using the post spacer including the polymer elastomers and the inorganic nanoparticles and by repairing the post spacer after the light emitting layer is formed by evaporation, so that the protrusions on the surface of the post spacer change from sharp to smooth, and the heights of the protrusions are greatly decreased, so as to prevent the protrusions from piercing the encapsulation layer, thereby avoiding failure of encapsulation, ensuring effectively the encapsulation effect, eliminating the problem of failure of encapsulation of the sub-pixels, and improving the field rate.

In an exemplary implementation, part of light emitted by the organic light emitting layer is emitted after passing through the pixel define layer and being incident to the encapsulation layer. In the display substrate, the pixel define layer is usually made of organic materials with higher refractive indexes. According to the optical principle, when light is incident from an optically denser medium with a higher refractive index to an optically thinner medium with a lower refractive index, if its incident angle is greater than the total reflection angle relative to an interface between the optically denser medium and the optically thinner medium, the total reflection will occur. Thus, part of light inside the pixel define layer will be totally reflected at the interface of the pixel define layer, so that the light will be confined in the pixel define layer, causing light loss and decreasing the light output efficiency and luminance. According to the present invention, the transmission direction of the light in the pixel define layer can be changed by using the pixel define layer and the post spacer including the inorganic nanoparticles and by light refraction and/or reflection through the inorganic nanoparticles, such that the total reflection of the light by the interface of the pixel define layer is eliminated, thereby improving the light output efficiency effectively and increasing the luminance effectively.

In an exemplary implementation, external water and oxygen may permeate into the organic light emitting layer through the pixel define layer. In the display substrate, the pixel define layer is usually made of organic materials, and the water and oxygen permeabilities are high, so the ability to block water and oxygen is weak. According to the present invention, due to the stronger ability of the inorganic nanoparticles to block water and oxygen, the ability of the pixel define layer and the post spacer to block water and oxygen is improved effectively by using the pixel define layer and the post spacer including the inorganic nanoparticles, such that the probability of external water and oxygen penetrating into the organic light emitting layer through the pixel define layer and the post spacer is decreased, thereby increasing the service life of the display substrate effectively.

The present disclosure further provides a method for manufacturing a display substrate. In an exemplary implementation, the method of manufacturing the display substrate may include:
S1: forming a pixel define layer and a post spacer on a driving structure layer, wherein the post spacer is disposed on a surface of the pixel define layer at one side away from the driving structure layer, and an orthographic projection of the post spacer on a substrate is within an orthographic projection of the pixel define layer on the substrate;
S2: forming an organic light emitting layer by evaporation using a fine metal mask; and
S3: repairing the post spacer, wherein there are protrusions on a surface of the post spacer at one side away from the driving structure layer, heights of the protrusions being less than 0.2 µm.

In an exemplary implementation, materials of the post spacer include polymer elastomers and nanoparticles, the polymer elastomers include at least one of polyurethane, polysiloxane and liquid crystal block polymer, an appearance of the polymer elastomers is a cross-linked network formed by chemical connection, and diameters of meshes of the cross-linked network are 0.5 µm to 2.0 µm; repairing the post spacer may include:

irradiating the post spacer with ultraviolet light, wherein expansion and contraction of the cross-linked network of the polymer elastomers occur under the irradiation of the ultraviolet light, so that the protrusions on the surface of the post spacer change from sharp to smooth, the heights of the protrusions being less than 0.2 µm.

In an exemplary implementation, an irradiation intensity of the ultraviolet light is 5 mW/cm² to 20 mW/cm², and irradiation time of the ultraviolet light is 100 seconds to 300 seconds.

In an exemplary implementation, forming the pixel define layer and the post spacer on the driving structure layer may include: forming the pixel define layer on the driving structure layer; and forming the post spacer on the pixel define layer using a post spacer mask; and

irradiating the post spacer with the ultraviolet light may include providing a post spacer mask on the display substrate and irradiating the post spacer using an ultraviolet light device, the ultraviolet light passing through a light transmission area of the post spacer mask to irradiate the post spacer.

In an exemplary implementation, forming the pixel define layer and the post spacer on the driving structure layer may include: forming the pixel define layer and the post spacer on the driving structure layer through the same running of patterning process using a gray tone mask; and

irradiating the post spacer with the ultraviolet light includes providing the gray tone mask on the display substrate and irradiating the post spacer using an ultraviolet light device, the ultraviolet light passing through a light transmission area of the gray tone mask to irradiate the post spacer.

In the method of manufacturing the display substrate of the present disclosure, the encapsulation effect is ensured effectively by using the post spacer including the polymer elastomers and the inorganic nanoparticles and repairing the post spacer after the light emitting layer is formed by evaporation, thereby improving the light output efficiency effectively and increasing the service life of the display substrate effectively. In addition, the manufacturing method of the present disclosure provides minor improvements to the processes, has high compatibility, is simple in process realization, is easy to implement, and has high production efficiency, low production cost and high field rate.

The present disclosure further provides a display device which includes the display substrate in accordance with the aforementioned embodiments. The display device may be any product or component with a display function, such as a mobile phone, a tablet computer, a television, a display, a notebook computer, a digital photo frame, a navigator, Car display, smart watch, or smart bracelet.

Although the implementations of the present disclosure are disclosed as above, the contents described are used to only easily understand the implementations of the present disclosure, and are not intended to limit the present disclosure. Those skilled in the art may make any modification and alternation in forms of implementation and details without departing from the spirit and scope of the present disclosure. However, the scope of patent protection of the present disclosure should still be subject to the scope defined by the appended claims.

1. A display substrate, comprising:
a pixel define layer and a post spacer disposed on a driving structure layer, wherein the post spacer is disposed on a surface of the pixel define layer at a side away from the driving structure layer, and an orthographic projection of the post spacer on a substrate is within an orthographic projection of the pixel define layer on the substrate; there is a protrusion on a surface of the post spacer at a side away from the driving structure layer, a height of the protrusion being less than 0.2 µm.

2. The display substrate according to claim 1, wherein materials of the post spacer comprise polymer elastomers and nanoparticles, and a proportion of the nanoparticles in the post spacer is 0.5 wt% to 5 wt%.

3. The display substrate according to claim 2, wherein a diameter of the nanoparticles is 20 nm to 100 nm.

4. The display substrate according to claim 2, wherein the nanoparticles comprise methyl modified inorganic nanoparticles.

5. The display substrate according to claim 4, wherein the methyl modified inorganic nanoparticles comprise at least one of methyl modified inorganic silicon oxide nanoparticles, methyl modified inorganic zinc oxide nanoparticles and methyl modified inorganic zirconium oxide nanoparticles.

6. The display substrate according to claim 2, wherein the polymer elastomers comprise at least one of polyurethane, polysiloxane and liquid crystal block polymer, an appearance of the polymer elastomers is a cross-linked network formed by chemical connection, and a diameter of meshes of the cross-linked network is 0.5 µm to 2.0 µm.

7. The display substrate according to claim 1, wherein a height of the post spacer is 1 µm to 1.5 µm.

8. The display substrate according to claim 1, wherein materials of the pixel define layer and the post spacer are the same.

9. The display substrate according to claim 1, wherein the post spacer and the pixel define layer form an integrated structure.

10. A display device comprising the display substrate according to claim 1.

11. A method for manufacturing a display substrate, comprising:
forming a pixel define layer and a post spacer on a driving structure layer, wherein the post spacer is disposed on a surface of the pixel define layer at a side away from the driving structure layer, and an orthographic projection of the post spacer on a substrate is within an orthographic projection of the pixel define layer on the substrate;
forming an organic light emitting layer by evaporation using a fine metal mask; and
repairing the post spacer, wherein there is a protrusion on a surface of the post spacer at a side away from the driving structure layer, a height of the protrusion being less than 0.2 µm.

12. The method according to claim 11, wherein materials of the post spacer comprise polymer elastomers and nanoparticles, the polymer elastomers comprise at least one of polyurethane, polysiloxane and liquid crystal block polymer, an appearance of the polymer elastomers is a cross-linked network formed by chemical connection, and a diameter of meshes of the cross-linked network is 0.5 µm to 2.0 µm, wherein repairing the post spacer comprises:
irradiating the post spacer with ultraviolet light, wherein expansion and contraction of the cross-linked network of the polymer elastomers occur under irradiation of the ultraviolet light, so that the protrusion on the surface of the post spacer changes from sharp to smooth.

13. The method according to claim 12, wherein an irradiation intensity of the ultraviolet light is 5 mW/cm² to 20 mW/cm², and irradiation time of the ultraviolet light is 100 seconds to 300 seconds.

14. The method according to claim 12, wherein
forming the pixel define layer and the post spacer on the driving structure layer comprises: forming the pixel define layer on the driving structure layer; and forming the post spacer on the pixel define layer using a post spacer mask; and
irradiating the post spacer with the ultraviolet light comprises: providing the post spacer mask on the display substrate and irradiating the post spacer using an ultraviolet light device, the ultraviolet light passing through a light transmission area of the post spacer mask to irradiate the post spacer.

15. The method according to claim 12, wherein
forming the pixel define layer and the post spacer on the driving structure layer comprises: forming the pixel define layer and the post spacer on the driving structure layer through a same patterning process using a gray tone mask; and
irradiating the post spacer with the ultraviolet light comprises: providing the gray tone mask on the display substrate and irradiating the post spacer using an ultraviolet light device, the ultraviolet light passing through a light transmission area of the gray tone mask to irradiate the post spacer.

16. The display substrate according to claim 3, wherein the polymer elastomers comprise at least one of polyurethane, polysiloxane and liquid crystal block polymer, an appearance of the polymer elastomers is a cross-linked network formed by chemical connection, and a diameter of meshes of the cross-linked network is 0.5 µm to 2.0 µm.

17. The display substrate according to claim 4, wherein the polymer elastomers comprise at least one of polyurethane, polysiloxane and liquid crystal block polymer, an appearance of the polymer elastomers is a cross-linked network formed by chemical connection, and a diameter of meshes of the cross-linked network is 0.5 µm to 2.0 µm.

18. The display substrate according to claim 5, wherein the polymer elastomers comprise at least one of polyurethane, polysiloxane and liquid crystal block polymer, an appearance of the polymer elastomers is a cross-linked network formed by chemical connection, and a diameter of meshes of the cross-linked network is 0.5 µm to 2.0 µm.

19. The display substrate according to claim 2, wherein a height of the post spacer is 1 µm to 1.5 µm.

20. The display substrate according to claim 3, wherein a height of the post spacer is 1 µm to 1.5 µm.
